(19) United States
(12) Patent Application Publication
(10) Pub. No.: US 2024/0103072 A1
(43) Pub. Date: Mar. 28, 2024

(54) TESTING A SEMICONDUCTOR DEVICE USING X-RAYS

(71) Applicant: Intel Corporation, Santa Clara, CA (US)

(72) Inventors: Patrick PARDY, Hillsboro, OR (US); Kimberlee CELIO, Portland, OR (US); Sanchari SEN, Beaverton, OR (US); May Ling OH, Portland, OR (US); Shuai ZHAO, Beaverton, OR (US); Joshua W. KEVEK, Portland, OR (US); Evgeny Gregory NISENBOIM, Haifa (IL); Amir RAVEH, Haifa (IL); Boris SIMKHOVICH, Haifa (IL); Charles A. PETERSON, Hillsboro, OR (US); Kevin JOHNSON, Portland, OR (US); Martin Eric Gostasson VON HAARTMAN, Portland, OR (US); Eli ABU AYOB, Haifa (IL); Xianghong TONG, Portland, OR (US)

(21) Appl. No.: 17/952,017

(22) Filed: Sep. 23, 2022

(51) Int. Cl. G01R 31/302

(52) U.S. Cl. CPC G01R 31/302

(57) ABSTRACT

Embodiments described herein may be related to apparatuses, processes, systems, and/or techniques for using x-rays to alter or observe circuits within a semiconductor device before, during or after a test of the semiconductor device. Other embodiments may be described and/or claimed.

### FIELD

Embodiments of the present disclosure generally relate to the field of semiconductor manufacturing, and in particular to testing for defects and marginalities within a semiconductor device.

### BACKGROUND

Continued growth in virtual machines, cloud computing, and portable devices will continue to increase the demand for high density transistors within chips and packages. In addition, there will be an increased need for high quality components, including transistors, with an improved efficiency in identifying device defects in a semiconductor device.

### BRIEF DESCRIPTION OF THE DRAWINGS

FIG. 1 shows a cross-section side view of a semiconductor device that includes a transistor layer with a front side metal layer and a back side metal layer, with a cross-section side view diagram of an x-ray beam focused on a target location in the transistor layer, in accordance with various embodiments.

FIG. 2 shows a cross-section side view of a diagram of an x-ray tool that includes a layer with an aperture to focus an x-ray beam on a target location, in accordance with various embodiments.

FIGS. 3A-3D shows top-down views and cross-section side views of configurations of layers that include an aperture that is used to focus an x-ray beam on a target location, in accordance with various embodiments.

FIG. 4 shows a plurality of x-ray beam intensity profiles as a function of aperture diameter, in accordance with various embodiments.

FIG. 5 illustrates a system for testing semiconductor devices that includes an x-ray source, aperture, holder for a semiconductor device, and a casing to provide x-ray shielding, in accordance with various embodiments.

FIGS. 6A-6B illustrate another system for testing semiconductor devices, in accordance with various embodiments.

FIG. 7 illustrates an example process for altering a location within a semiconductor device using x-rays, in accordance with various embodiments.

FIG. 8 illustrates a computing device in accordance with one implementation of the invention.

FIG. 9 illustrates an interposer that includes one or more embodiments of the invention.

### DETAILED DESCRIPTION

Embodiments described herein may be related to apparatuses, processes, systems, and/or techniques for using x-rays to alter circuits or other structures within a semiconductor device before or during a test of the semiconductor device. The test may be related to fault isolation, failure analysis, or general debug of the semiconductor device, and/or testing the operational characteristics of the device.

In some embodiments, an opaque layer that includes an aperture may be positioned between a generation source for an x-ray beam and the semiconductor device. During operation, the x-ray beam passes through the aperture, which causes the resulting x-ray beam to focus on a target location on or within the semiconductor device. When the x-ray beam passes through the aperture, the flux density of photons of the resulting x-ray beam, measured in photons per second per beam area (photons/second/beam area) significantly increases. In embodiments, the size of the aperture may be selected to define a focus distance, a flux density, and/or a resulting spot size for the target location of the resulting x-ray beam within the semiconductor device. In embodiments described herein, sub-micron beams with up to a four times higher flux density may be achieved at practical working distances within laboratory tools, facilitating x-ray fault isolation within advanced integrated circuits in semiconductor devices.

In embodiments, the target location in a semiconductor device may include circuitry or other components within a transistor layer of the semiconductor device, or may include areas within the metal layers. The energy of the x-rays may be selected so that the resulting x-ray beam will penetrate the metal layers to deliver a high density of photons to the target location.

In embodiments, these techniques may be used to introduce local shifts in circuit timing as well as to introduce transistor current-voltage (IV) alterations within circuitry. These effects may subsequently be evaluated by operational testing of the circuitry. In embodiments, this technique may be used to locate timing issues and physical defects or faults within the circuitry. In embodiments, these techniques may also be used to interrogate the state of circuitry, leveraging, for example, voltage- and/or current-based x-ray scattering contrast.

In legacy implementations, laser-assisted device alteration (LADA) is used in the infrared (IR) and visible optical spectral ranges for semiconductor product debugging and fault isolation work. These legacy techniques are based on illuminating and imaging frontside bond wired, C4 backside flip chip, and 3-D semiconductor integrated circuits with visible light and/or near IR (NIR) light, and may be based on laser scanning microscopy (LSM). These legacy techniques are used to penetrate through bulk silicon, and to induce photo-excitation and/or thermal excitation of a target location within the semiconductor devices through raster laser scanning or stationery means. These legacy techniques also cause local timing shifts and transistor current-voltage (IV) alterations, which are used to facilitate the location of circuit defects.

Other legacy implementations may include lock-in thermography, infrared emission microscopy (IREM), logic state imaging (LSI), and thermal imaging to provide failure analysis, fault isolation, or other debug capabilities by locating, detecting, or imaging through metal layers, dielectric layers, or other layers of the semiconductor device, which may be referred to as device stack materials, during testing and/or electrical conditioning. However, in the case of legacy thermal techniques, although they may penetrate optically opaque structures, they are limited to a few microns in spatial resolution due to heat spreading/diffusion through the material stack of the semiconductor devices. As a result, these legacy techniques are of limited value in the precise identification of a target location within a semiconductor device circuit.

In addition, with the introduction of back side power delivery technologies within semiconductor device circuitry, which include metal layers on either side of a layer of transistor circuitry, these legacy techniques now become even less effective due to the high optical absorption of the metal layers. As a result, these legacy fault isolation and physical debugging techniques cannot be used in circuitry within a semiconductor device, which may also be referred to as circuit stacks, where transistors are enclosed from both sides with front and back side metal layers that optical light cannot penetrate.

In embodiments, the apparatus, systems, and techniques described in embodiments herein may be part of a suite of tools, which may be referred to as an ecosystem, that may replace legacy optical technologies used to interrogate semiconductor devices such as C-4 flip chip devices. Components within this suite may use different sources for x-ray beam generation, which may be focused and incident on an electrically biased and/or conditioned integrated circuits. In some embodiments, these sources for x-ray beam generation may include a small circular or other-shaped aperture to produce increased x-ray focusing and photon density. In addition, the suite of tools may include vibration reduction-based tester configurations to improve accuracy. In addition, the tools may also facilitate thermal control and detection schemes to produce data for on die behavior during operational testing. In embodiments, this data may be used to provide product design teams with information to drive improvements for future design iterations, as well as the ability to improve fabrication and reduce circuit defects during manufacturing, which may also be referred to as FAB stepping(s).

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

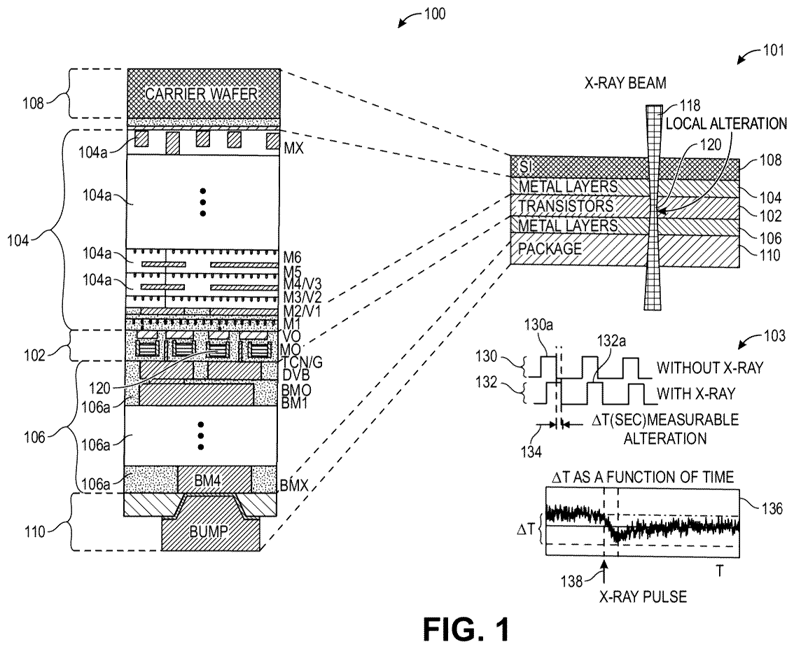

FIG. 1 shows a cross-section side view of a semiconductor device that includes a transistor layer with a front side metal layer and a back side metal layer, with a cross-section side view diagram of an x-ray beam focused on a target location in the transistor layer, in accordance with various embodiments. Semiconductor device 100 illustrates a cross-section side view that includes a transistor layer 102 and a target location 120 within the transistor layer 102.

On one side of the transistor layer 102 there is a front side interconnect layer 104 that may include metal layers 104a that may be used to provide electrical routing with various components within the transistor layer 102. On the other side of the transistor layer 102, opposite the front side interconnect layer 104, there is a back side interconnect layer 106 that may include metal layers 106a that may be used to provide electrical routing with various components within the transistor layer 102 and with a package 110 may be physically coupled with the back side interconnect layer 106. In embodiments, the package 110 may be a back side interconnect medium. A topside material 108, which may include silicon, may be physically coupled with the front side interconnect layer 104, and may be used to support the semiconductor device 100 during handling while the semiconductor device 100 is undergoing testing. Non-limiting examples of a semiconductor device 100 may include a central processing unit (CPU), chipset, a graphics processing unit (GPU), multi-tiled device, and the like.

In embodiments, when the semiconductor device 100 is undergoing a test, the target location 120 within the transistor layer 102 may be altered either before or during the test. After the alteration, the semiconductor device 100 may be operated, for example by electrically activating the semiconductor device 100 and operational data collected and analyzed to determine the impact of the alteration. The data can also be observed dynamically during real-time device operation. In embodiments, the test may be performed in order to conduct a failure analysis, fault isolation, and/or other debugging processes of the semiconductor device 100. During a complete testing cycle, a number of different alterations of the target location 120 may be performed. In embodiments, during the complete testing cycle there may be a plurality of target locations (not shown) similar to target location 120 that are altered within the semiconductor device 100.

In embodiments, for example, the target location 120 may be a portion of a circuit or of a junction within the transistor layer 102. In embodiments, the alteration to the target location 120 may cause a defect in the circuit or the junction, or may cause other operational alterations of the circuit or the junction. In embodiments, the alteration of the portion of the circuit at the target location 120 may be performed using a focused x-ray beam.

Diagram 101 shows an embodiment of an x-ray beam 118, which is focused on the target location 120. In embodiments, the x-ray beam 118 is injected into the target location 120, and imparts a high flux density of photons into the target location 120 either before or during a test of the semiconductor 100 to alter the circuit or the junction, either for a short or for a long duration of time. Diagram 101 shows a high-level diagram of the semiconductor device 100, including the topside material 108, front side interconnect layer 104, transistor layer 102, back side interconnect layer 106, and portion of the package 110.

In embodiments, the alteration of the target location 120 may involve the destruction of a component, for example a circuit, transistor, or a junction, within the semiconductor device 100 in order to determine the operational effect if the circuit or the junction at target location 120 is not working correctly. In other embodiments, as shown in diagram 103, the x-ray beam 118 may be used to modify the operation of a circuit or a junction at the target location 120 in order to introduce a timing shift within an electrical signal. Such modification may be short- or long-lived, and may manifest in a change in the timing of the rising and/or falling edges of the output signal.

For example, a normal circuit output signal 130 with pulses 130a may be observed from the semiconductor device 100 during operation without the x-ray beam 118. When the x-ray beam 118 is applied to the target location 120, an altered output signal 132 may result during operation of the semiconductor device 100 with pulses 132a that are shifted by a length of time (Δt) 134. Graph 136 shows an example of Δt as a function of time (T), where the x-ray beam 118 was implemented at time 138. This may be referred to as perturbing timing. Using these techniques, circuit defects or circuit speed paths may be identified, isolated, and potentially mitigated. In other embodiments, transistor current-voltage (IV) alterations may be introduced at target location 120, which may change circuit operation characteristics or allow for analyzing transistor behavior at different conditions. In embodiments, observations of the circuit current or voltage state may be made.

It should be appreciated that although the target location 120 is shown within the transistor layer 102, the target location 120 may be at any location within the semiconductor device 100. For example, a target location may be within the front side interconnect layer 104 or may be within the back side interconnect layer 106.

In embodiments, the x-ray beam 118 is used to penetrate either the metal found in the front side interconnect layer 104, and/or the back side interconnect layer 106, to reach the target location 120 within the transistor layer 102, or within another part of the semiconductor device 100, to deliver photons to alter or observe circuit state/behavior.

In embodiments, specific energies of the x-ray beam 118 may be selected to penetrate the metal layers 104a within the front side interconnect layer 104, and the metal layers 106a within the back side interconnect layer 106, to reach the transistor layer 102 and target location 120. In embodiments, an exposure time for the x-ray beam 118 onto the target location 120 may be adjusted to induce a meaningful alteration in the target location 120. In embodiments, this exposure time may be based upon the incident flux density of the x-ray beam 118 where a higher flux density enables faster, higher magnitude alteration in the target location 120.

In embodiments, the x-ray beam 118 may be used in a continuous source mode, where the x-ray beam 118 is focused continuously on the target location 120. In embodiments, a pulsed x-ray beam, such as that supplied by a synchrotron, may be used. In embodiments, the x-ray beam 118 may be a gated or modulated x-ray pulse train that may be applied in a synchronized or a non-synchronized timing mode with the circuit operation.

In embodiments, the x-ray processes described herein with respect to the semiconductor device 100 may also be applied to other devices, including wirebonded semiconductor devices, controlled collapse chip connection (C4) flip chip semiconductor devices, three-dimensional (3D-IC) integrated circuit semiconductor devices, or other types semiconductor devices. In embodiments, examples of components that may be perturbed or observed at the target location 120 may include transistors, collections of transistors, or interconnects. In embodiments, other components in the semiconductor device 100 may be perturbed or observed, including front side or back side metal traces.

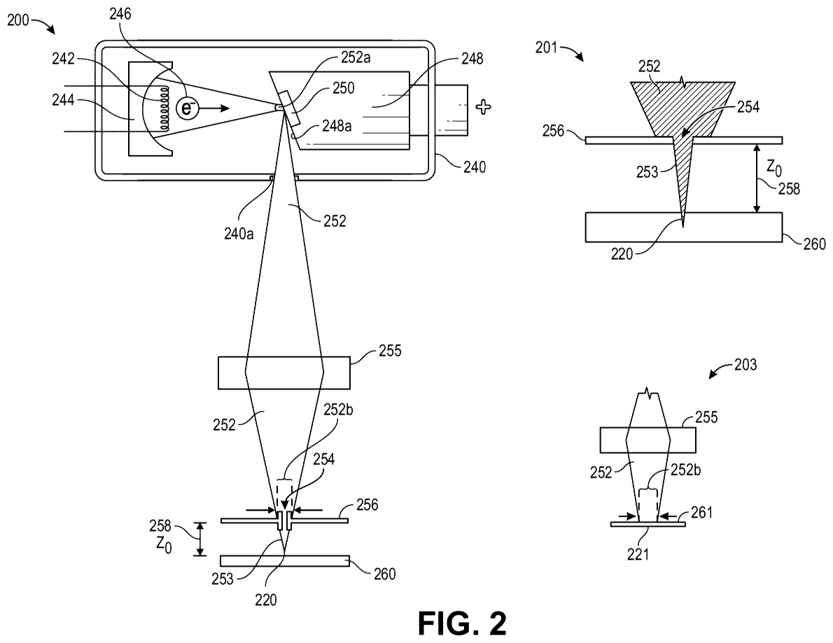

FIG. 2 shows a cross-section side view of a diagram of an x-ray tool that includes a layer with an aperture to focus an x-ray beam on a target location, in accordance with various embodiments. In embodiments, X-ray tool 200 may include a casing 240, which may include glass, that surrounds a filament 242 that is proximate to a cathode 244 used to generate electrons 246. The filament 242 and the cathode 244 may be referred to as an electron gun. In embodiments, there is a vacuum within the casing 240. An anode 248, which may include copper, includes a target 250 on a beveled end 248a of the anode 248. In embodiments, the target 250 may include tungsten, copper, chromium or some other material.

During operation, the generated electrons 246 strike and excite the target 250, which results in emission of an x-ray beam 252. The x-ray beam 252 will have characteristics that are associated with the material composition of the target 250. In embodiments, the cathode 244 may have a cup shape to facilitate the focus of the generated electrons 246 against the target 250. The generated x-ray beam 252 may emerge through a casing window 240a within the casing 240.

The x-ray beam 252 has a source spot size 252a proximate to the target 250 where the x-ray beam 252 is generated. The x-ray beam 252 then widens, as it passes through the casing window 240a and travels to the focusing optics 255. In embodiments, the focusing optics 255 may include mirrors, multilayer mirrors, gratings, a Fresnel lens, and the like.

A width of the x-ray beam 252 narrows after it passes through the focusing optics 255 and reaches a spot size 252b on a layer 256 above an aperture 254. In embodiments, the layer 256 may be an opaque layer that does not allow x-rays to penetrate. For example, layer 256 may be a layer that includes a film of gold or tungsten. The aperture 254 may also be referred to as a focusing aperture. In embodiments, the aperture 254 may have any shape, including a circle, a rectangle, an oval, or a slit. The spot size 252b is a function of the source spot size 252a convoluted with, or spread by, a point spread function (PSF) as determined by the focusing optics 255. In some embodiments, the aperture 254 and layer 256 may not be present, and the x-ray beam 252 may directly strike the target location 220.

When the x-ray beam 252 passes through the aperture 254, the resulting x-ray beam 253 is diffracted by the aperture 254 and is focused on a target location 220 within a target device 260. In embodiments, target location 220 may be similar to target location 120 of FIG. 1, and target device 260 may be similar to semiconductor device 100 of FIG. 1.

In embodiments, the resulting x-ray beam 253 after passing through the aperture 254 refocuses again and may reach a higher flux density. In embodiments, the focus of the resulting x-ray beam 253 on the target location 220 may be determined by the dimension of the aperture 254. The level of flux density increase within the resulting x-ray beam 253 depends upon the dimension of the aperture 254 and a distance Zo 258 between the aperture 254 and the target location 220.

In embodiments, a dimension and/or geometry of the aperture 254 may be selected in order to focus the x-ray beam 252 into a resulting x-ray beam 253 with a specific higher flux density. In some embodiments, the coherence length of the x-ray beam 252 may place limits on the maximum dimensions of the aperture 254. In particular, the dimension of the aperture 254 may be similar to or smaller than the coherence length of the x-ray beam 252. In other embodiments, the dimension of the aperture 254 may be larger than the coherence length of the x-ray beam 252, for example but not limited to three times larger. In embodiments, the energy of the x-ray beam 252, and therefore of the resulting x-ray beam 253, may be selected to enable penetration of a target location 220 that may be deep inside the target device 260.

In embodiments, specific energies of the x-ray beam 252 may be selected to penetrate the metal layers 104a within the front side interconnect layer 104, and the metal layers 106a within the back side interconnect layer 106, to reach the transistor layer 102 and target location 120 of FIG. 1, which may be similar to target location 220. In embodiments, an exposure time for the resulting x-ray beam 253 onto the target location 220 may be adjusted to induce a meaningful alteration in the target location 220. In embodiments, this exposure time may be based upon the incident flux density of the resulting x-ray beam 253 where a higher flux density enables faster, higher magnitude alteration in the target location 220.

In embodiments, the x-ray beam 252 may be used in a continuous source mode, where the resulting x-ray beam 253 is focused continuously on the target location 220. In embodiments, the x-ray beam 252 may be a pulsed x-ray beam, such as that supplied by a synchrotron. In embodiments, the x-ray beam 252 may be a gated or modulated x-ray pulse train that may be applied in a synchronized or a non-synchronized timing mode with the circuit operation.

Diagram 201 shows an enlargement of the x-ray beam 252, aperture 254, layer 256, resulting x-ray beam 253, the target device 260, and the target location 220 within the target device 260. The embodiments and techniques described herein may be applied to any type of target device 260, not just semiconductor devices, where a target location 220 within the target device 260 is to receive photons in a focused resulting x-ray beam 253. In embodiments, target device 260 may include capacitors and/or other circuits that may be embedded within a metal layer of a semiconductor device. In other embodiments, a target device 260 may include biological samples, tissues, or other targets for non-linear x-rays effects and light-matter interactions.

Diagram 203 shows an example of a legacy implementation without the layer 256 that includes the aperture 254. In this legacy implementation, the x-ray beam 252, after passing through the focusing optics 255, lands on the target 261, which may be similar to target device 260. However, the area of the spot size 252b is larger than the target at location 221, which may be similar to target location 220 and may have insufficient focus and flux density to affect an alteration on the target location 221. In addition, the flux density of the x-ray beam 252 at the point that it intersects the target 261 has not changed, and may not provide sufficient photons to affect an alteration on the target location 221.

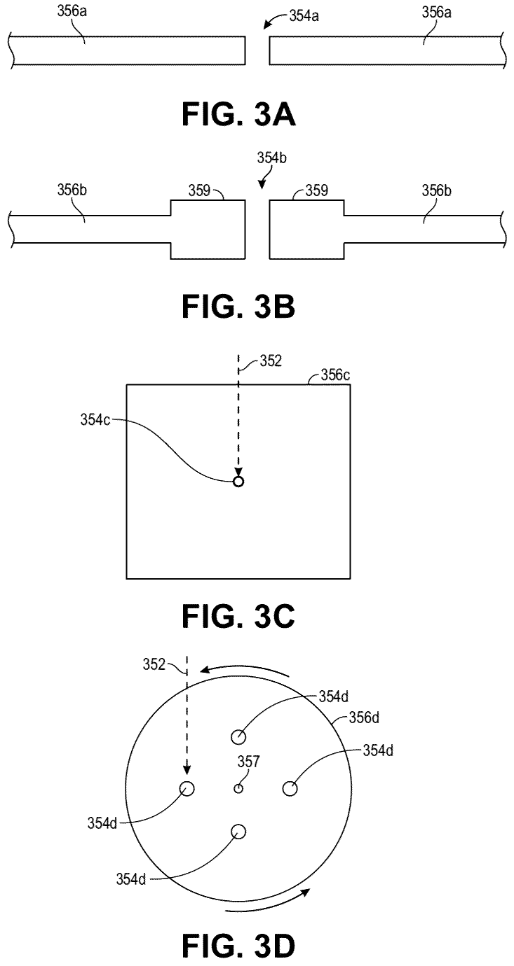

FIGS. 3A-3D shows top-down views and cross-section side views of configurations of layers that include an aperture that is used to focus an x-ray beam on a target location, in accordance with various embodiments. FIG. 3A shows a cross-section side view of a layer 356a, which may be similar to layer 256 of FIG. 2. Aperture 354a, which may be similar to aperture 254 of FIG. 2, extends through the layer 356a. The layer 356a has a constant thickness on either side of the aperture 354a. In some embodiments, the aperture 354 may be coupled with a moving stage (not shown) that allows various X-Y-Z orientations. In embodiments, this may allow rapid scanning of semiconductor devices within the bounds of the size of the x-ray beam 252 of FIG. 2. In embodiments, the aperture 354a may have a cone shape.

FIG. 3B shows a cross-section side view of a layer 356b, which may be similar to layer 256 of FIG. 2. Aperture 354b, which may be similar aperture 254 of FIG. 2, extends through the layer 356b. However, in this embodiment there are features 359 that are a part of the layer 356b and on either side of the aperture 354b. In embodiments, the features 359 may include an enhanced thickness to better block the x-ray beam, such as x-ray beam 252 of FIG. 2.

FIG. 3C shows a top-down view of a layer 356c which may be similar to layer 256 of FIG. 2. Aperture 354c, which may be similar to aperture 254 of FIG. 2, extends through the layer 356c. An x-ray beam 352, which may be similar to x-ray beam 252 of FIG. 2, intersects the aperture 354c, where the resulting x-ray beam (not shown) is focused on a target location, such as target location 220 of FIG. 2, to create a high flux density focused x-ray beam, which may be similar to resulting x-ray beam 253 of FIG. 2, on the other side of the aperture 354c. In embodiments, the aperture 354c may have a fixed location with respect to the x-ray beam 352. In embodiments, the aperture 354c may have a number of different top view shapes, including circle, rectangle, oval, or a slit.

FIG. 3D shows a top-down view of a layer 356d, which may be similar to layer 256 of FIG. 2, that may be rotated around an axis 357. A plurality of apertures 354d, which may be similar to aperture 254 of FIG. 2, may rotate around the axis 357, where at least some of the plurality of apertures 354d may intersect the x-ray beam 352 to create a pulse of a high flux density focused x-ray beam on the other side of one of the plurality of apertures 354d. In embodiments, layer 356d may rotate within a plane of the layer 356d. In embodiments, a speed of rotation of the layer 356d may be determined based upon the timing and intensity of x-ray beam 352 that intersects one of the plurality of apertures 354d. In embodiments, the layer 356d may be an opaque layer.

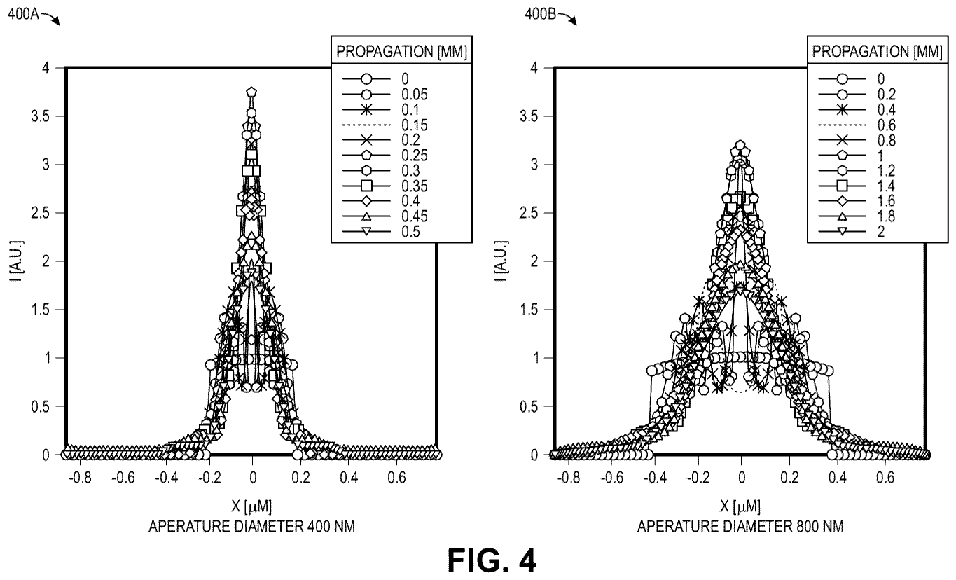

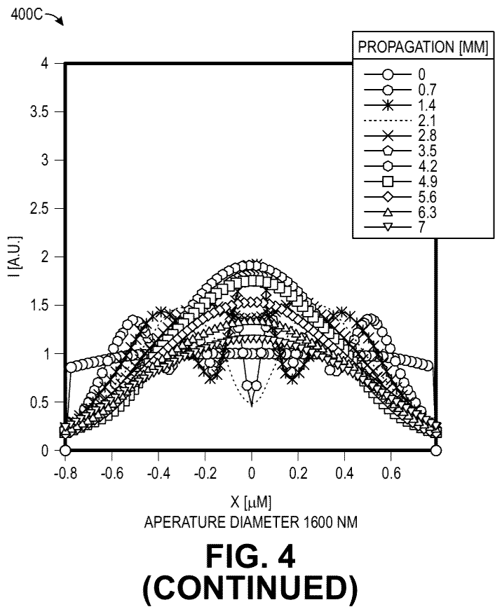

FIG. 4 shows a plurality of x-ray beam intensity profiles as a function of aperture diameter, in accordance with various embodiments. Diagrams 400A, 400B, 400C are graphs that show simulation result profiles of x-ray intensity as a function of aperture diameter, and the distance the x-ray beam, for example 253 of FIG. 2, propagates after passing through the aperture, such as aperture 254 of FIG. 2. In particular, diagrams 400A, 400B, 400C compare focus distance, which may be similar to distance Zo of FIG. 2, between the aperture, such as aperture 254 of FIG. 2, and a target location, which may be similar to target location 220 of FIG. 2, and the resulting flux density.

Diagram 400A shows a most focused profile resulting at a focus distance of 0.25 mm with a 400 nm diameter aperture. Diagram 400B shows a most focused profile resulting at a focus distance of 1 mm with a 800 nm diameter aperture. Diagram 400C shows a most focused profile resulting at a focus distance of 4.2 mm with a 1600 nm diameter aperture. The focus distances of 0.25 mm, 1 mm, and 4.2 mm are sufficiently long to be implemented as part of an x-ray-based semiconductor test protocol.

The simulations assumed a 1.5406 Å (Cu Kα line) x-ray beam of 5 μm size with 1 μm coherence length, and for the 1600 nm diameter aperture the most focused profile does not have the same flux density gain as for smaller apertures, the flux density gain drops as the aperture dimension becomes comparable to the coherence length of the x-ray entering the aperture, for example aperture 254 of FIG. 2.

In simulations, a change in monochromatic x-ray wavelength to 1.3703 Å, which is 1 kilo electron volt (keV) higher than the Cu Kα line, leads to about 10% reduction in the efficiency of the aperture focusing if the focus distance is forced to that of the Cu Kα line.

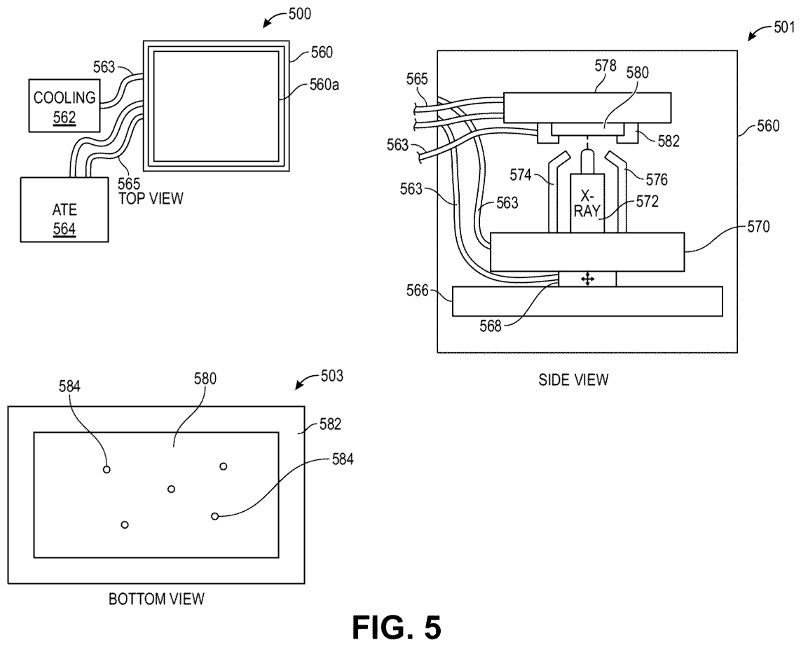

FIG. 5 illustrates a system for testing semiconductor devices that includes an x-ray source, holder for a semiconductor device, and a casing to provide x-ray shielding, in accordance with various embodiments. Various embodiments may include an aperture for additional focusing of the x-ray beam, which may be similar to aperture 254 of FIG. 2. Diagrams 500, 501, 503 show various views of embodiments of a testing system, which may also be referred to as a full testing ecosystem, that may be used for x-ray assisted device alteration in order to perform fault isolation, failure analysis, and/or physical debugging of a semiconductor device.

Diagram 500 shows a top-down view of a system for testing semiconductor devices that includes an enclosure 560, which may also be referred to as a housing. In embodiments, x-ray shield 560a may surround all or a portion of the enclosure 560. In embodiments, the x-ray shield 560a may prevent or reduce x-rays from escaping outside of the enclosure 560. In embodiments, a cooling mechanism 562 may be used to cool components, described below, that are within the enclosure 560. In embodiments, the cooling mechanism 562 may supply a regular source of cool fluids, such as cooled water, or may provide cooled gases such as cooled air or cooled Freon, through a cooling loop 563.

In embodiments, automated test equipment (ATE) 564 may be electrically coupled with one or more components that are within the enclosure 560, using cabling 565. In embodiments, the ATE 564 may be referred to as a controller. Note that in embodiments, a length of the cabling 565 may be chosen to minimize any vibration that may be transmitted between the ATE 564 and the components within the enclosure 560 that may negatively impact imaging and testing. In embodiments, the cabling 565 may include a bundle of individual cables. In embodiments, the ATE 564 may include a signal generator or other testing instrumentation, for example but not limited to function and signal generators and/or power supplies. In embodiments, the cabling 565 and the cooling loop 563 may enter the enclosure 560 through feedthrough ports or baffles (not shown) at a side of the enclosure 560.

Although the diagrams in FIG. 5 show the system for testing semiconductor devices in a particular orientation, embodiments may not have this particular orientation. For example, the system may be orientated in a top down and upward looking configuration. For example, the cooling embodiments described below may include transparent mediums such as a diamond window, sapphire windows, or metal plates that may have drilled access holes for x-ray propagation to the semiconductor device that is under test testing and/or characterization.

Diagram 501 shows a cross-section side view of various components within the enclosure 560 that may be used to perform x-ray-based semiconductor testing. In embodiments, a base 566 may be used to support a raster stage 568, which in turn supports a platform 570. Note that in embodiments, the raster stage 568 may be able to move the platform 570, with respect to the base 566, in an X, Y, or Z direction. In other embodiments, the test fixture 578 may be rastered while the x-ray assembly on the platform 570 remains fixed, or both may be rastered.

The platform 570 may support an x-ray tool 572, which may be similar to x-ray tool 200 of FIG. 2. In embodiments, the platform 570 may also support a detector 574, which may include a fluorescence detector. In embodiments, the platform 570 may also support a microscope 576, which may include near IR capabilities. In embodiments, the detector 574 and the microscope 576 may be used for aligning the x-ray tool 572.

In embodiments, a test fixture 578, which in some embodiments may include a tester board (not shown) coupled with a device under test (DUT) 580, may be above the x-ray tool 572. In other embodiments, the test fixture 578 may be below the x-ray tool 572, or in some other orientation, such as a side-on orientation. In embodiments, the DUT 580 may be in any orientation with respect to the x-ray tool 572, for example to change an incident angle on the DUT 580 for flux photons. The test fixture 578 may be electrically coupled with the ATE 564 using one or more cables of the cabling 565. In embodiments, the DUT 580 may be electrically and/or physically coupled with the test fixture 578. In embodiments, the DUT 580 may be similar to semiconductor device 100 of FIG. 1, or target device 260 of FIG. 2. In embodiments, a clamp 582, which may be referred to as a holder, may be used to secure the DUT 580 onto the test fixture 578.

In embodiments, the clamp 582 may completely surround or may partially surround the DUT 580. In embodiments, the clamp 582 may include a cooling feature (not shown) that may be used to cool the DUT 580 during testing. In embodiments, the cooling feature may include a metal-based plate or optical transparent diamond and/or sapphire-based window with ambient air or fluid forced through the cooling feature during operation. In embodiments, the cooling feature of the clamp 582 may couple with the cooling loop 563 that is coupled with the cooling mechanism 562 of diagram 500. In embodiments, there may be other thermal solutions that are in thermal contact with the DUT 580, such as heatsinks (not shown) that may include diamond and/or other low x-ray absorption materials that allow photons to pass through the heatsink and reach the DUT 580.

Diagram 503 shows a bottom-up view of the DUT 580 that is surrounded by the clamp 582. During operation, in embodiments, the ATE 564 may send signals to the raster stage 568 to orient the x-ray tool 572 in an X, Y, or Z direction in order to focus on various target locations 584 within the DUT 580. In embodiments, the x-ray tool 572 may be used to create a circuit alteration at the target locations 584. In embodiments, the ATE 564 may also send signals to the test fixture 578 to send various electric signals through the DUT 580 to analyze the resulting performance of the DUT 580 with and without x-ray-driven circuit alterations.

In embodiments, the ATE 564 may receive input from the microscope 576 in order to align the x-ray tool 572 with the target locations 584. In embodiments, the input from the microscope 576 may include electronic data and may include visual data that may be viewed by an operator in order to position the x-ray tool 572 along a target location 584. In addition, the ATE 564 may also receive input from the detector 574 to enable x-ray alignment to the DUT target locations, where the feature on the DUT, which may be added or pre-existing, are apparent in the x-ray fluorescence signal.

In embodiments, a series of testing loops may be performed by the ATE 564 in order to create temporary or long-lasting alterations at the target locations 584, for example to evaluate circuit timing changes or to change current-voltage characteristics of a transistor circuit as described above with respect to FIG. 2. In embodiments, the x-ray tool 572 may produce x-rays in a synchronized mode, where x-rays instructions from the ATE 564 may control modulation of the x-ray beam through, for example, a chopping or shuttering mechanism between the x-ray source and the DUT. The ATE 564 may also send electronic signals to the DUT 580 through the test fixture 578. In embodiments, the x-ray tool 572 may produce x-rays in a non-synchronized mode, where for example, the x-ray beam is continuous and not modulated. In some embodiments, the x-ray tool 572 may be moved along the DUT 580, for example in a scanning technique. In other embodiments of scanning techniques, the DUT 580 may be moved with respect to the x-ray tool 572.

In embodiments, the raster stage 568 may be physically coupled with the test fixture 578, and as a result move the DUT 580 with respect to the platform 570 which may be in a fixed position. In addition, in embodiments there may be heating mechanisms (not shown) proximate to the DUT 580 that may be used to keep at least a portion of the environment within the enclosure 560 free of frost. In embodiments, a heating mechanism (not shown) may be used to provide annealing to restore or partially restore alteration of the DUT 580 that may occur during the x-ray exposure.

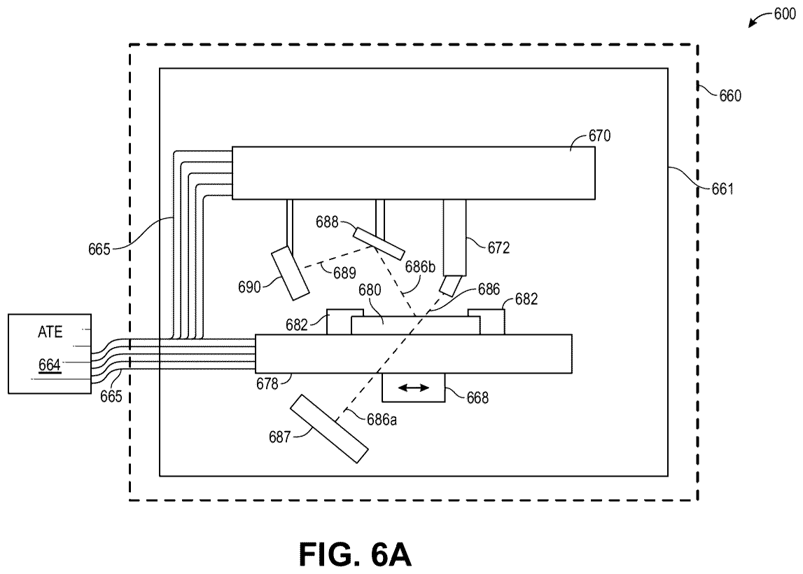

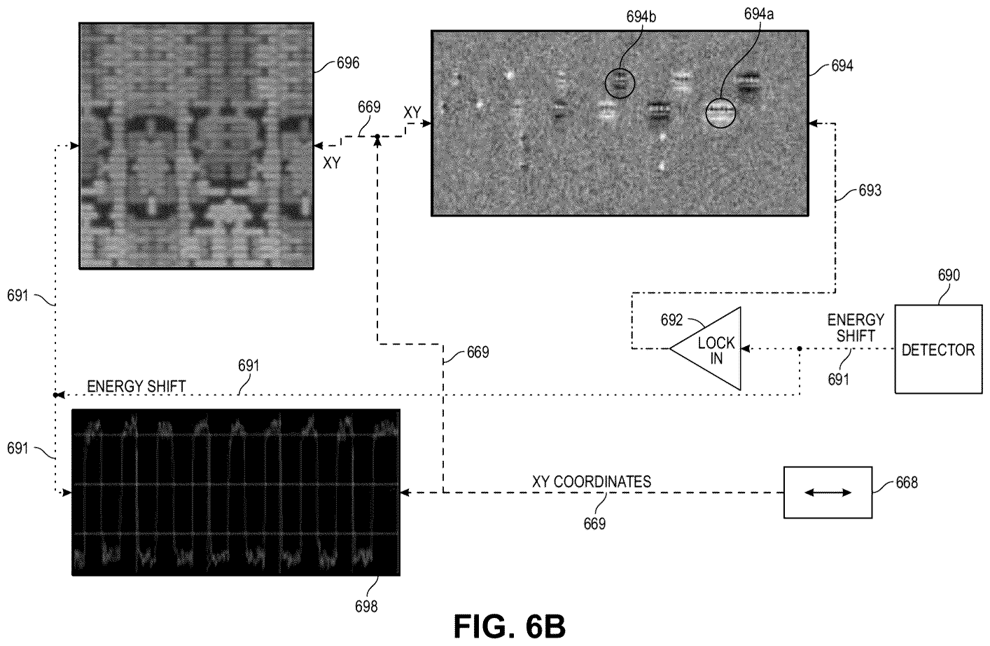

FIG. 6A-6B illustrate another system for testing semiconductor devices, in accordance with various embodiments. FIG. 6A shows a cross-section side view of tester ecosystem for observing or detecting circuit and/or voltage states of an operational device using x-rays. System 600 includes a test environment 660 that may be coupled with an ATE 664, which may be similar to ATE 564 of FIG. 5. In embodiments, the test environment 660 may include a shield 661 that may be used to prevent or reduce x-rays from escaping beyond the shield 661. In embodiments, the ATE 664 may be electrically coupled with a test fixture 678, which may be similar to test fixture 578 of FIG. 5, using cabling 665 which may be similar to cabling 565 of FIG. 5. In embodiments, the test fixture 678 may include a hardware socket and/or associate electrical connections and clamp mechanisms to enable testing/operation of the DUT 680 as described above with respect to test fixture 578 of FIG. 5.

In embodiments, a DUT 680, which may be similar to DUT 580 of FIG. 5, may be electrically and physically coupled to the test fixture 678. In embodiments, the DUT 680 may be attached or otherwise secured to the test fixture 678 using clamps 682, which may be referred to as a holder or holders. In embodiments, the test fixture 678 may be coupled with a raster stage 668, which may be similar to raster stage 568 of FIG. 5 that is able to accurately move the test fixture 678 in an X and a Y direction.

A platform 670, which may be similar to platform 570 of FIG. 5, may include an x-ray tool 672, which may be similar to the x-ray tool 572 of FIG. 5, or which may be a projection-style x-ray imaging tool. In embodiments, during operation, the x-ray tool 672 may emit an x-ray beam 686 toward the DUT 680, where a portion 686a of the x-ray beam 686 may penetrate the DUT 680. The resulting portion 686a of the x-ray beam 686 may intersect a 2D detector 687.

In addition, during operation, a portion 686b of the x-ray beam 686 may scatter off of the DUT 680. The portion of the x-ray beam 686b may intersect a crystal monochromater, which selects a defined wavelength of the x-ray radiation, and transmits the selected defined wavelength 689 to a point or an array detector 690. The array detector 690 may then produce a resulting image, which may then be analyzed and used as described below with respect to FIG. 6B.

In embodiments, the cabling 665 may also electrically couple the ATE 664 with the platform 670, which in turn may control the operation of the x-ray tool 672, the crystal monochromater 688, and the point or array detector 690. An X-Y position of the DUT 680, with respect to the x-ray tool 672, may also be determined by the ATE 664. In embodiments, the DUT 680 may be operated during one or more test loops by the ATE 664.

FIG. 6B shows embodiments of how the data collected by the test environment 660, in particular with respect to the point or array detector 690, may be routed and/or used. In embodiments, an output 691 of the point or array detector 690 may travel to a lock-in amplifier 692. In embodiments, the lock-in amplifier 692 is an instrument that may be used to improve the signal-to-noise ratio of a modulated signal by identifying and amplifying the modulated signal. In embodiments, the lock-in amplifier 692 may be electrically coupled with a resulting output 693 that may be shown in an x-ray intensity toggle imaging map 694, where operational states of various circuits, for example circuits 694a, 694b may be displayed. In embodiments, the output 691 of the point or array detector 690 may also be used to display a voltage-induced x-ray spectral shift display 696, or an x-ray voltage probe display 698.

In embodiments, individual features of the x-ray intensity toggle imaging map 694, voltage-induced x-ray spectral shift display 696, and the x-ray voltage probe display 698 may be identified by X-Y coordinates of the location of the DUT 680 that may be provided by the raster stage 668 using communication link 669 or by the array detector 690. In embodiments, the X-Y coordinates may be provided by the ATE 664.

In embodiments, precise locations for the X-Y coordinates during the application of the x-ray tool 672 and the DUT 680, an incident x-ray signature may be created through the various detectors, and an optimal signal-to-noise ratio (SnR) created by use of lock-in techniques to analyze how the x-ray impacts the circuit spectrum and other signatures such as transistor state and/or x-ray spectral shift.

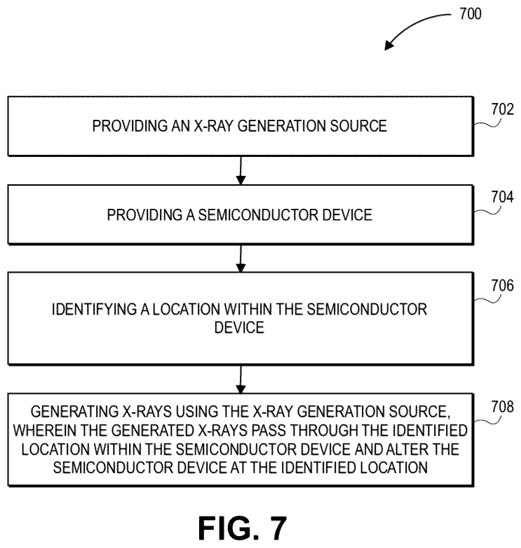

FIG. 7 illustrates an example process for altering a location within a semiconductor device using x-rays, in accordance with various embodiments. In embodiments, the process may be performed by any of the systems, processes, or techniques described herein, in particular with respect to FIGS. 1-6B.

At block 702, the process may include providing an x-ray generation source. In embodiments, the source for generating x-rays may be similar to x-ray tool 200 of FIG. 2, x-ray tool 572 of FIG. 5, or x-ray tool 672 of FIG. 6A.

At block 704, the process may further include providing a semiconductor device. In embodiments, the semiconductor device may be similar to semiconductor device 100 or the semiconductor device shown in diagram 101 of FIG. 1, target device 260 of FIG. 2, DUT 580 of FIG. 5, or DUT 680 of FIG. 6A.

At block 706, the process may further include identifying a location within the semiconductor device. In embodiments, the location within the semiconductor device may be similar to target location 120 of FIG. 1, target location 220 of FIG. 2, or target locations 584 of FIG. 5.

At block 708, the process may further include generating x-rays using the x-ray generation source, wherein the generated x-rays pass through the identified location within the semiconductor device and alter the semiconductor device proximate to the identified location. In embodiments, the generated x-rays may be similar to x-ray beam 118 of FIG. 1, x-ray beam 252 of FIG. 2, or x-ray beam 352 of FIG. 3D. In embodiments, the x-ray generation source may be similar to x-ray tool 200 of FIG. 2, or x-ray tool 572 of FIG. 5.

Implementations of embodiments of the invention may be formed or carried out on a substrate, such as a semiconductor substrate. In one implementation, the semiconductor substrate may be a crystalline substrate formed using a bulk silicon or a silicon-on-insulator substructure. In other implementations, the semiconductor substrate may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device, or other similar devices, may be built falls within the spirit and scope of the present invention. In embodiments, the materials may include life science materials that may include one or more biological samples.

A plurality of transistors, such as metal-oxide-semiconductor field-effect transistors (MOSFET or simply MOS transistors), may be fabricated on the substrate. In various implementations of the invention, the MOS transistors may be planar transistors, nonplanar transistors, or a combination of both. Nonplanar transistors include FinFET transistors such as double-gate transistors and tri-gate transistors, and wrap-around or all-around gate transistors such as nanoribbon and nanowire transistors. Although the implementations described herein may illustrate only planar transistors, it should be noted that the invention may also be carried out using nonplanar transistors.

Each MOS transistor includes a gate stack formed of at least two layers, a gate dielectric layer and a gate electrode layer. The gate dielectric layer may include one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric layer to improve its quality when a high-k material is used.

The gate electrode layer is formed on the gate dielectric layer and may consist of at least one P-type workfunction metal or N-type workfunction metal, depending on whether the transistor is to be a PMOS or an NMOS transistor. In some implementations, the gate electrode layer may consist of a stack of two or more metal layers, where one or more metal layers are workfunction metal layers and at least one metal layer is a fill metal layer.

For a PMOS transistor, metals that may be used for the gate electrode include, but are not limited to, ruthenium, palladium, platinum, cobalt, nickel, and conductive metal oxides, e.g., ruthenium oxide. A P-type metal layer will enable the formation of a PMOS gate electrode with a workfunction that is between about 4.9 eV and about 5.2 eV. For an NMOS transistor, metals that may be used for the gate electrode include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An N-type metal layer will enable the formation of an NMOS gate electrode with a workfunction that is between about 3.9 eV and about 4.2 eV.

In some implementations, the gate electrode may consist of a “U”-shaped structure that includes a bottom portion substantially parallel to the surface of the substrate and two sidewall portions that are substantially perpendicular to the top surface of the substrate. In another implementation, at least one of the metal layers that form the gate electrode may simply be a planar layer that is substantially parallel to the top surface of the substrate and does not include sidewall portions substantially perpendicular to the top surface of the substrate. In further implementations of the invention, the gate electrode may consist of a combination of U-shaped structures and planar, non-U-shaped structures. For example, the gate electrode may consist of one or more U-shaped metal layers formed atop one or more planar, non-U-shaped layers.

In some implementations of the invention, a pair of sidewall spacers may be formed on opposing sides of the gate stack that bracket the gate stack. The sidewall spacers may be formed from a material such as silicon nitride, silicon oxide, silicon carbide, silicon nitride doped with carbon, and silicon oxynitride. Processes for forming sidewall spacers are well known in the art and generally include deposition and etching process steps. In an alternate implementation, a plurality of spacer pairs may be used, for instance, two pairs, three pairs, or four pairs of sidewall spacers may be formed on opposing sides of the gate stack.

As is well known in the art, source and drain regions are formed within the substrate adjacent to the gate stack of each MOS transistor. The source and drain regions are generally formed using either an implantation/diffusion process or an etching/deposition process. In the former process, dopants such as boron, aluminum, antimony, phosphorous, or arsenic may be ion-implanted into the substrate to form the source and drain regions. An annealing process that activates the dopants and causes them to diffuse further into the substrate typically follows the ion implantation process. In the latter process, the substrate may first be etched to form recesses at the locations of the source and drain regions. An epitaxial deposition process may then be carried out to fill the recesses with material that is used to fabricate the source and drain regions. In some implementations, the source and drain regions may be fabricated using a silicon alloy such as silicon germanium or silicon carbide. In some implementations the epitaxially deposited silicon alloy may be doped in situ with dopants such as boron, arsenic, or phosphorous. In further embodiments, the source and drain regions may be formed using one or more alternate semiconductor materials such as germanium or a group III-V material or alloy. And in further embodiments, one or more layers of metal and/or metal alloys may be used to form the source and drain regions.

One or more interlayer dielectrics (ILD) are deposited over the MOS transistors. The ILD layers may be formed using dielectric materials known for their applicability in integrated circuit structures, such as low-k dielectric materials. Examples of dielectric materials that may be used include, but are not limited to, silicon dioxide (SiO₂), carbon doped oxide (CDO), silicon nitride, organic polymers such as perfluorocyclobutane or polytetrafluoroethylene, fluorosilicate glass (FSG), and organosilicates such as silsesquioxane, siloxane, or organosilicate glass. The ILD layers may include pores or air gaps to further reduce their dielectric constant.

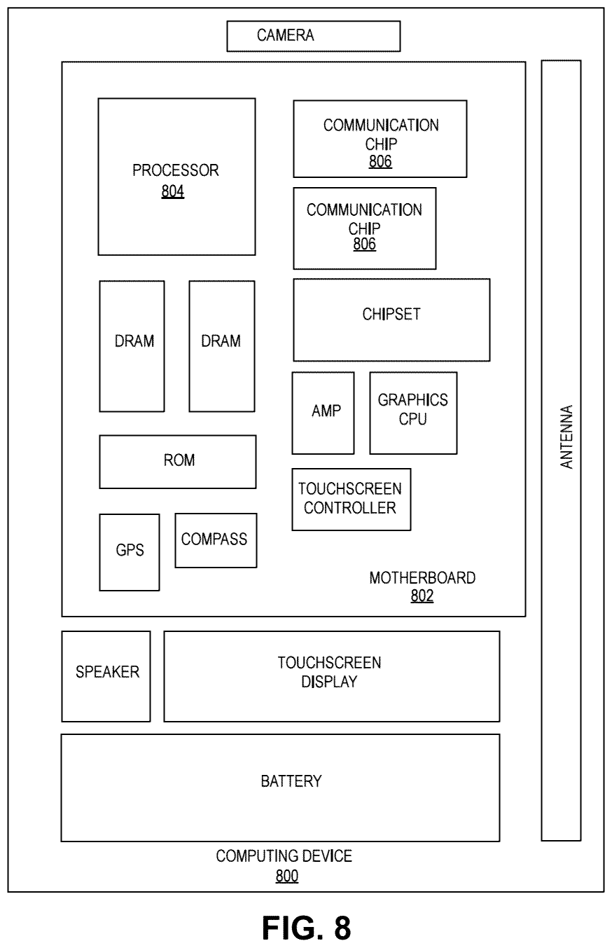

FIG. 8 illustrates a computing device 800 in accordance with one implementation of the invention. The computing device 800 houses a board 802. The board 802 may include a number of components, including but not limited to a processor 804 and at least one communication chip 806. The processor 804 is physically and electrically coupled to the board 802. In some implementations the at least one communication chip 806 is also physically and electrically coupled to the board 802. In further implementations, the communication chip 806 is part of the processor 804.

Depending on its applications, computing device 800 may include other components that may or may not be physically and electrically coupled to the board 802. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 806 enables wireless communications for the transfer of data to and from the computing device 800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 806 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 800 may include a plurality of communication chips 806. For instance, a first communication chip 806 may be dedicated to shorter range wireless communications such as Wi-Fi and Bluetooth and a second communication chip 806 may be dedicated to longer range wireless communications such as GPS, EDGE, GPRS, CDMA, WiMAX, LTE, Ev-DO, and others.

The processor 804 of the computing device 800 includes an integrated circuit die packaged within the processor 804. In some implementations of the invention, the integrated circuit die of the processor includes one or more devices, such as MOS-FET transistors built in accordance with implementations of the invention. The term “processor” may refer to any device or portion of a device that processes electronic data from registers and/or memory to transform that electronic data into other electronic data that may be stored in registers and/or memory.

The communication chip 806 also includes an integrated circuit die packaged within the communication chip 806. In accordance with another implementation of the invention, the integrated circuit die of the communication chip includes one or more devices, such as MOS-FET transistors built in accordance with implementations of the invention.

In further implementations, another component housed within the computing device 800 may contain an integrated circuit die that includes one or more devices, such as MOS-FET transistors built in accordance with implementations of the invention.

In various implementations, the computing device 800 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 800 may be any other electronic device that processes data.

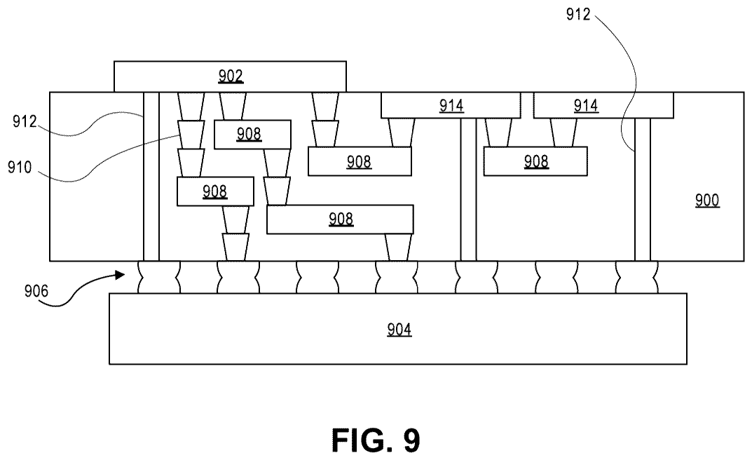

FIG. 9 illustrates an interposer 900 that includes one or more embodiments of the invention. The interposer 900 is an intervening substrate used to bridge a first substrate 902 to a second substrate 904. The first substrate 902 may be, for instance, an integrated circuit die. The second substrate 904 may be, for instance, a memory module, a computer motherboard, or another integrated circuit die. Generally, the purpose of an interposer 900 is to spread a connection to a wider pitch or to reroute a connection to a different connection. For example, an interposer 900 may couple an integrated circuit die to a ball grid array (BGA) 906 that can subsequently be coupled to the second substrate 904. In some embodiments, the first and second substrates 902/904 are attached to opposing sides of the interposer 900. In other embodiments, the first and second substrates 902/904 are attached to the same side of the interposer 900. And in further embodiments, three or more substrates are interconnected by way of the interposer 900.

The interposer 900 may be formed of an epoxy resin, a fiberglass-reinforced epoxy resin, a ceramic material, or a polymer material such as polyimide. In further implementations, the interposer may be formed of alternate rigid or flexible materials that may include the same materials described above for use in a semiconductor substrate, such as silicon, germanium, and other group III-V and group IV materials.

The interposer 900 may include metal interconnects 908 and vias 910, including but not limited to through-silicon vias (TSVs) 912. The interposer 900 may further include embedded devices 914, including both passive and active devices. Such devices include, but are not limited to, capacitors, decoupling capacitors, resistors, inductors, fuses, diodes, transformers, sensors, and electrostatic discharge (ESD) devices. More complex devices such as radio-frequency (RF) devices, power amplifiers, power management devices, antennas, arrays, sensors, and MEMS devices may also be formed on the interposer 900. In accordance with embodiments of the invention, apparatuses or processes disclosed herein may be used in the fabrication of interposer 900.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. Rather, the scope of the invention is to be determined entirely by the following claims, which are to be construed in accordance with established doctrines of claim interpretation.

The following paragraphs describe examples of various embodiments.

### EXAMPLES

Example 1 is a method comprising: providing an x-ray generation source; providing a semiconductor device; identifying a location within the semiconductor device; and generating x-rays using the x-ray generation source, wherein the generated x-rays pass through the identified location within the semiconductor device and alter the semiconductor device proximate to the identified location.

Example 2 includes the method of example 1, wherein to alter the semiconductor device proximate to the identified location further includes to change an operational characteristic of the semiconductor device.

Example 3 includes the method of examples 1 or 2, wherein generating x-rays using the x-ray generation source further includes generating x-rays while the semiconductor device is undergoing operational testing.

Example 4 includes the method of example 3, wherein undergoing operational testing further includes a selected one or more of: observing a current or observing a voltage state of the semiconductor device.

Example 5 includes the method of examples 3 or 4, wherein generating x-rays using the x-ray generation source further comprises synchronizing generating x-rays with the operational testing of the semiconductor device.

Example 6 includes the method of examples 1, 2, 3, 4, or 5, wherein the semiconductor device includes one or more metal layers between the identified location and the x-ray generation source.

Example 7 is a system for testing a semiconductor device, the system comprising: an x-ray tool, the x-ray tool including a source for generating x-rays; a holder, wherein the holder is coupled with the semiconductor device; and a controller, wherein the controller is electrically coupled with the x-ray tool and the holder, and wherein the controller is configured to position an x-ray beam generated by the x-ray tool with respect to a target location within the semiconductor device.

Example 8 includes the system of example 7, wherein the holder is electrically coupled with the semiconductor device.

Example 9 includes the system of example 8, wherein the controller is configured to synchronize generation of x-rays on the target location within the semiconductor device with an electrical operation of the semiconductor device.

Example 10 includes the system of example 9, wherein the controller is configured to receive operational data from the semiconductor device.

Example 11 includes the system of examples 7, 8, 9, or 10, wherein the x-ray tool further includes a camera; and wherein a positioning of the semiconductor device is based at least in part on an output of the camera.

Example 12 includes the system of example 11, wherein the camera includes a selected one or more of: a fluorescence detector or a near infrared (NIR) microscope.

Example 13 includes the system of examples 7, 8, 9, 10, 11, or 12, further comprising a shield that surrounds at least a portion of the x-ray tool and the holder.

Example 14 includes the system of examples 7, 8, 9, 10, 11, 12, or 13, further comprising a cooling system that is thermally coupled with the holder and with the semiconductor device.

Example 15 includes the system of examples, 8, 9, 10, 11, 12, 13, or 14, wherein the holder further includes a clamp.

Example 16 is an apparatus comprising: a source for generating x-rays; a target location for the x-rays generated by the source; a layer between the source and the target location; and an aperture in the layer, wherein the aperture extends from a first side of the layer to a second side of the layer opposite the first side, and wherein the aperture is between the source and the target location.

Example 17 includes the apparatus of example 16, wherein a diameter of the aperture is determined based upon a distance between the layer and the target location.

Example 18 includes the apparatus of examples 16 or 17, wherein the layer is opaque.

Example 19 includes the apparatus of examples 16, 17, or 18, wherein the aperture in the layer further includes a plurality of apertures in the layer, and wherein the layer is configured to rotate around an axis.

Example 20 includes the apparatus of examples 16, 17, 18, or 19, wherein a diameter of the aperture ranges from 0.11 μm to 3.0 μm.

Example 21 includes the apparatus of examples 16, 17, 18, 19, or 20, wherein the aperture is a selected one of: a circle, a rectangle, an oval, or a slit.

Example 22 includes the apparatus of examples 16, 17, 18, 19, 20, or 21, further comprising optics between the source and the layer.

Example 23 includes the apparatus of example 22, wherein the optics include a selected one or more of: a mirror, a grating, a lens, and/or a Fresnel lens.

Example 24 includes the apparatus of examples 16, 17, 18, 19, 20, 21, 22, or 23, wherein the target location is within a semiconductor device, and wherein the target location is a selected one or more of: a transistor layer or a metal layer.

Example 25 includes the apparatus of example 24, wherein the semiconductor device includes a first plurality of metal layers above the transistor layer and/or a second plurality of metal layers below the transistor layer.

What is claimed is:

1. A method comprising:
providing an x-ray generation source;
providing a semiconductor device;
identifying a location within the semiconductor device; and
generating x-rays using the x-ray generation source, wherein the generated x-rays pass through the identified location within the semiconductor device and alter the semiconductor device proximate to the identified location.

2. The method of claim 1, wherein to alter the semiconductor device proximate to the identified location further includes to change an operational characteristic of the semiconductor device.

3. The method of claim 1, wherein generating x-rays using the x-ray generation source further includes generating x-rays while the semiconductor device is undergoing operational testing.

4. The method of claim 3, wherein undergoing operational testing further includes a selected one or more of: observing a current or observing a voltage state of the semiconductor device.

5. The method of claim 3, wherein generating x-rays using the x-ray generation source further comprises synchronizing generating x-rays with the operational testing of the semiconductor device.

6. The method of claim 1, wherein the semiconductor device includes one or more metal layers between the identified location and the x-ray generation source.

7. A system for testing a semiconductor device, the system comprising:
an x-ray tool, the x-ray tool including a source for generating x-rays;
a holder, wherein the holder is coupled with the semiconductor device; and
a controller, wherein the controller is electrically coupled with the x-ray tool and the holder, and wherein the controller is configured to position an x-ray beam generated by the x-ray tool with respect to a target location within the semiconductor device.

8. The system of claim 7, wherein the holder is electrically coupled with the semiconductor device.

9. The system of claim 8, wherein the controller is configured to synchronize generation of x-rays on the target location within the semiconductor device with an electrical operation of the semiconductor device.

10. The system of claim 9, wherein the controller is configured to receive operational data from the semiconductor device.

11. The system of claim 7, wherein the x-ray tool further includes a camera; and wherein a positioning of the semiconductor device is based at least in part on an output of the camera.

12. The system of claim 11, wherein the camera includes a selected one or more of: a fluorescence detector or a near infrared (NIR) microscope.

13. The system of claim 7, further comprising a shield that surrounds at least a portion of the x-ray tool and the holder.

14. The system of claim 7, further comprising a cooling system that is thermally coupled with the holder and with the semiconductor device.

15. The system of claim 7, wherein the holder further includes a clamp.

16. An apparatus comprising:
a source for generating x-rays;
a target location for the x-rays generated by the source;
a layer between the source and the target location; and
an aperture in the layer, wherein the aperture extends from a first side of the layer to a second side of the layer opposite the first side, and wherein the aperture is between the source and the target location.

17. The apparatus of claim 16, wherein a diameter of the aperture is determined based upon a distance between the layer and the target location.

18. The apparatus of claim 16, wherein the layer is opaque.

19. The apparatus of claim 16, wherein the aperture in the layer further includes a plurality of apertures in the layer, and wherein the layer is configured to rotate around an axis.

20. The apparatus of claim 16, wherein a diameter of the aperture ranges from 0.1 μm to 3.0 μm.

21. The apparatus of claim 16, wherein the aperture is a selected one of: a circle, a rectangle, an oval, or a slit.

22. The apparatus of claim 16, further comprising optics between the source and the layer.

23. The apparatus of claim 22, wherein the optics include a selected one or more of: a mirror, a grating, a lens, and/or a Fresnel lens.

24. The apparatus of claim 16, wherein the target location is within a semiconductor device, and wherein the target location is a selected one or more of: a transistor layer or a metal layer.

25. The apparatus of claim 24, wherein the semiconductor device includes a first plurality of metal layers above the transistor layer and/or a second plurality of metal layers below the transistor layer.
